(19) United States
(12) Patent Application Publication
(10) Pub. No.: US 2026/0136896 A1
(43) Pub. Date: May 14, 2026

(54) SEMICONDUCTOR STRUCTURE, SEMICONDUCTOR PACKAGE, AND MANUFACTURING METHOD THEREOF

(71) Applicant: Samsung Electronics Co., Ltd., Suwon-si (KR)

(72) Inventor: Sungeun Jo, Suwon-si (KR)

(73) Assignee: Samsung Electronics Co., Ltd., Suwon-si (KR)

(21) Appl. No.: 19/077,376

(22) Filed: Mar. 12, 2025

(30) Foreign Application Priority Data
Nov. 14, 2024 (KR) 10-2024-0162390

(51) Int. Cl. H01L 21/66; H01L 21/48; H01L 23/31; H01L 23/538; H01L 25/00; H01L 25/18

(52) U.S. Cl. CPC H10P 74/273; H10W 70/05; H10W 70/611; H10W 70/65; H10W 90/00; H10W 90/401; H10W 74/111

(57) ABSTRACT

A semiconductor structure may include a first die including: an internal circuit; a first connection pad configured to transmit an electrical signal or power between the internal circuit and an outside of the first die; and dummy patterns electrically insulated from the internal circuit. The semiconductor structure may further include a redistribution layer including: a first redistribution pad electrically connected to the first connection pad; bonding patterns electrically connected to at least one of the dummy patterns; a first testing line connected to one of the bonding patterns, and a second testing line connected to another one of the bonding patterns, wherein the first die is on the redistribution layer, wherein at least one of the dummy patterns and at least two of the bonding patterns form a daisy chain, and wherein the first testing line and the second testing line are respective ends of the daisy chain.

### CROSS-REFERENCE TO RELATED APPLICATION

This application claims priority from Korean Patent Application No. 10-2024-0162390, filed on Nov. 14, 2024, in the Korean Intellectual Property Office, the disclosure of which is incorporated herein by reference in its entirety.

### BACKGROUND

### 1. Field

Some example embodiments of the present disclosure relate to a semiconductor structure, a manufacturing package, and a manufacturing method thereof.

### 2. Description of Related Art

Modern electronic devices demand high performance and energy efficiency. To meet the demands, semiconductor integrated circuit (IC) technology has been continuously evolving. Specifically, the rapid development of high-performance computing devices, artificial intelligence (AI) processors, graphics processing units (GPUs), data centers, and mobile devices requires further increased processing speed and further enhanced data processing capability.

To meet the demands, multi-die or system-on-chip (SoC) technology has been widely used in the semiconductor technology field. This technology enables multiple processors, memory, and various functional blocks to be integrated into one package to operate, contributing to improving performance and space efficiency.

The above is information the inventor(s) acquired during the course of conceiving the present disclosure, or already possessed at the time, and is not necessarily prior art publicly known before the present application was filed.

### SUMMARY

One or more example embodiments of the present disclosure may address at least the above problems and/or disadvantages and other disadvantages not described above. Also, the example embodiments of the present disclosure are not required to overcome the disadvantages described above, and an example embodiment may not overcome any of the problems described above.

According to some embodiments of the present disclosure, a semiconductor structure may be provided and include a first die including: an internal circuit; a first connection pad configured to transmit an electrical signal or power between the internal circuit and an outside of the first die; and a plurality of dummy patterns electrically insulated from the internal circuit. The semiconductor structure may further include a redistribution layer including: a first redistribution pad electrically connected to the first connection pad; a plurality of bonding patterns electrically connected to at least one of the plurality of dummy patterns; a first testing line connected to one of the plurality of bonding patterns, and a second testing line connected to another one of the plurality of bonding patterns, wherein the first die is on the redistribution layer, wherein at least one dummy pattern, from among the plurality of dummy patterns, and at least two bonding patterns, from among the plurality of bonding patterns, form a daisy chain, and wherein the first testing line and the second testing line are respective ends of the daisy chain.

According to some embodiments of the present disclosure, a semiconductor package may be provided and include a memory die; a processor die including an internal circuit, a first connection pad configured to transmit an electrical signal or power between the internal circuit and an outside of the processor die, and a plurality of dummy patterns electrically insulated from the internal circuit; and a redistribution layer including a first redistribution pad electrically connected to the first connection pad, a plurality of bonding patterns electrically connected to at least one of the plurality of dummy patterns, a first testing line connected to a first bonding pattern from among the plurality of bonding patterns, and a second testing line connected to a second bonding pattern from among the plurality of bonding patterns; and an interposer die that is configured to transmit an electrical signal between the memory die and the processor die, the interposer die being in the redistribution layer.

According to some embodiments of the present disclosure, a manufacturing method of a semiconductor package may be provided and include: forming a redistribution pad and a plurality of bonding patterns on a redistribution layer; forming a first testing line connected to a first bonding pattern from among the plurality of bonding patterns; forming a second testing line connected to a second bonding pattern from among the plurality of bonding patterns; placing the redistribution layer on a substrate; connecting a logic die to the redistribution layer, wherein the redistribution layer includes a connection pad and a plurality of dummy patterns, wherein the redistribution pad is connected to the connection pad, and at least one of the plurality of dummy patterns is connected to the plurality of bonding patterns such as to form a daisy chain, wherein the first testing line and the second testing line are respective ends of the daisy chain; surrounding the logic die with a molding material such that the logic die is not exposed to an outside of the semiconductor package; and dicing a structure, formed by the surrounding the logic die with the molding material, in a direction crossing the first testing line and the second testing line.

### BRIEF DESCRIPTION OF DRAWINGS

The above and/or other aspects will be more apparent by describing certain example embodiments, taken in conjunction with the accompanying drawings, in which:

FIG. 1 is a perspective view of a semiconductor package according to an embodiment;

FIG. 2 is a diagram illustrating a communication module and a system bus structure in the semiconductor package according to an embodiment;

FIG. 3 is a diagram illustrating an example of the semiconductor package according to an embodiment;

FIG. 4 is a cross-sectional view schematically illustrating a cross-section of a semiconductor structure according to an embodiment;

FIG. 5 is a top view of the semiconductor structure according to an embodiment;

FIG. 6 is a top view of the semiconductor structure of FIG. 5, including a partial cutaway view of a portion of a first die;

FIG. 7 is a top view of the semiconductor structure of FIG. 5, but where a first die and a second die are removed;

FIG. 8 is a top view of a redistribution layer according to an embodiment;

FIG. 9 is a top view of a redistribution layer according to an embodiment;

FIG. 10 is a top view of a semiconductor structure according to an embodiment;

FIG. 11 is a top view of the semiconductor structure of FIG. 10, including a partial cutaway view of a portion of a first die;

FIG. 12 is a top view of the semiconductor structure of FIG. 10, but where a first die and a second die are removed;

FIG. 13 is a drawing illustrating a method of manufacturing the semiconductor package according to an embodiment; and

FIG. 14 is a drawing illustrating a method of manufacturing a semiconductor package according to an embodiment.

### DETAILED DESCRIPTION

The following detailed structural and/or functional description is provided as an example only and various alterations and modifications may be made to the example embodiments. Here, the example embodiments are not construed as limited to the present disclosure, and all changes, equivalents, and replacements of the example embodiments are within the spirit and scope of the present disclosure.

Terms, such as “first,” “second,” and the like, may be used herein to describe components. Each of these terminologies is not used to define an essence, order, or sequence of a corresponding component but used merely to distinguish the corresponding component from other component(s). For example, a first component may be referred to as a second component, and similarly the second component may also be referred to as the first component.

It should be noted that if it is described that one component is “connected,” “coupled,” or “joined” to another component, a third component may be “connected, “coupled,” and “joined” between the first and second components, although the first component may be directly connected, coupled, or joined to the second component.

The singular forms “a,” “an,” and “the” are intended to include the plural forms as well, unless the context clearly indicates otherwise. It will be further understood that the terms “comprises/comprising” and/or “includes/including” when used herein, specify the presence of stated features, integers, steps, operations, elements, and/or components, but do not preclude the presence or addition of one or more other features, integers, steps, operations, elements, components and/or groups thereof.

As used herein, each of “A or B,” “at least one of A and B,” “at least one of A or B,” “A, B or C,” “at least one of A, B and C,” and “at least one of A, B, or C,” may include any one of the items listed together in the corresponding one of the phrases, or all possible combinations thereof.

Unless otherwise defined, all terms, including technical and scientific terms, used herein have the same meaning as commonly understood by one of ordinary skill in the art to which the present disclosure pertains. Terms, such as those defined in commonly used dictionaries, are to be interpreted as having a meaning that is consistent with their meaning in the context of the relevant art, and are not to be interpreted in an idealized or overly formal sense unless expressly so defined herein.

Hereinafter, non-limiting example embodiments will be described in detail with reference to the accompanying drawings. When describing the example embodiments with reference to the accompanying drawings, like reference numerals refer to like elements, and a repeated description related thereto may be omitted.

The same name may be used to describe an element included in the example embodiments described herein and an element having a common function. Unless otherwise stated, the descriptions of the example embodiments may be applicable to other example embodiments, and thus repeated descriptions are omitted for conciseness.

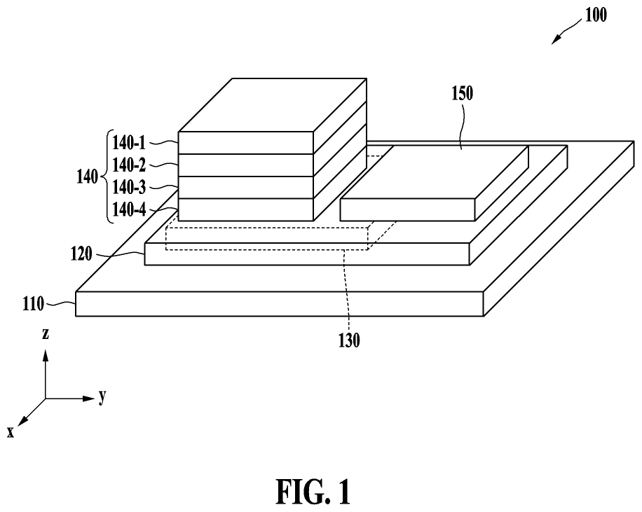

FIG. 1 is a perspective view of a semiconductor package according to an embodiment.

Referring to FIG. 1, a semiconductor package 100, according to an embodiment, may include a substrate 110, a redistribution layer 120, an interposer 130, a first die 150, and at least one second die 140. The redistribution layer 120 may be on the substrate 110, and the first die 150 and the at least one second die 140 may be on the redistribution layer 120.

The first die 150 may be a processor die (e.g., a logic die) and may include various types of processors, such as a central processing unit (CPU), a graphics processing unit (GPU), or a neural processing unit (NPU). This allows the efficient achievement of high-performance computing tasks, specifically, machine-learning tasks including artificial intelligence (AI) and deep neural network (DNN). A computing system including the semiconductor package 100 may perform various high-performance computing tasks including machine learning. Machine learning may be used for various application fields, such as data analysis, image processing, and/or natural language processing, in addition to AI and DNN. For example, the first die 150 may play a core role in processing data that is transmitted from the at least one second die 140.

The at least one second die 140 may be, for example, a memory stack. The at least one second die 140 may include a buffer die 140-4, that is a lowermost layer thereof, and at least one memory die 140-1, 140-2, or 140-3 that is stacked above the buffer die 140-4. The buffer die 140-4 may be referred to as a base die. The memory dies 140-1, 140-2, or 140-3 may store data and may transmit the stored data to the first die 150 through the buffer die 140-4. In this process, by temporarily storing a data signal and regenerating a signal for its transmission, the buffer die 140-4 may improve the stability and accuracy of the signal. In addition, the buffer die 140-4 may serve to improve the data processing speed of the whole system by minimizing latency and signal distortion that may occur during a data transmission process. For example, the buffer die 140-4 and the first die 150 may each include a physical layer (PHY) circuit that may reduce electrical loss occurring during a data transmission process.

The at least one second die 140 may include a plurality of memory dies 140-1, 140-2, 140-3, and 140-4 stacked in a multi-layer structure. In addition, the at least one second die 140 may not include a buffer die, and the interposer 130 that is in the redistribution layer 120 may play a buffer die role. The at least one second die 140 may be implemented as a high bandwidth memory (HBM) device, a low power double data rate (LPDDR) device, a graphics double data rate (GDDR) device, or a double data rate (DDR) device. In addition, unless otherwise stated, it should be noted that aspects of embodiments of the present disclosure may apply to and/or include 2.5-dimensional (D) and/or 3D packages in addition to HBM.

The interposer 130 may be embedded in the redistribution layer 120. The interposer 130 is an element that provides an electrical connection and may provide a physical conducting wire path for communication between the first die 150 and the at least one second die 140. In addition, the interposer 130 may not only transmit an electric signal but may also include an active circuit (e.g., a memory controller or a PHY circuit) configured to amplify and/or control a signal to improve the quality of the transmitted electric signal. For example, the interposer 130 may play a buffer die role in relaying data transmission between the first die 150 and the at least one second die 140. When the interposer 130 includes an active circuit, the interposer 130 may be referred to as a “third die,” “interposer die,” or “active interposer”. For example, the interposer 130 may be a type of semiconductor chip and may be implemented with silicon.

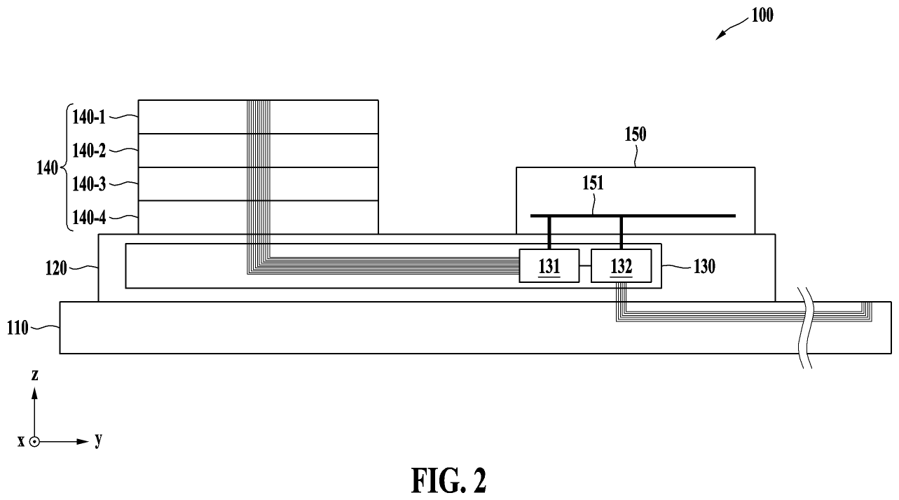

FIG. 2 is a diagram illustrating a communication module and a system bus structure in the semiconductor package according to an embodiment.

Referring to FIG. 2, a system bus 151 may manage data transmission between the first die 150 and the redistribution layer 120 or the interposer 130 in the semiconductor package 100. The system bus 151 may also be referred to as an on-chip bus (or an on-chip network) and may support communication among various processor cores. The system bus 151 may include an advanced microcontroller bus architecture (AMBA) advanced extensible interface (AXI) bus.

The first die 150 may include a plurality of processor cores (e.g., a CPU, a GPU, and an NPU) and the cores may be interconnected via the system bus 151. This structure may support the processor cores to efficiently communicate with the memory controller 131 and other important circuits. For example, the CPU may perform a task of reading or writing data in the at least one second die 140 through the memory controller 131 and the task may be rapidly performed via the system bus 151.

The semiconductor package 100 may include a communication module 132. The communication module 132 may serve to manage data transmission between the first die 150 and other processor dies (e.g., a processor die). The communication module 132 may include a die-to-die (D2D) communication module or a chip-to-chip (C2C) communication module. The communication module 132 may use a standard interface, such as universal chiplet interconnect express (UCIe) or peripheral component interconnect express (PCIe). For example, the D2D communication module may use a UCIe standard interface and the C2C communication module may use a PCIe standard interface.

The first die 150 may be directly connected to, for example, the memory controller 131 placed on the interposer 130. This structure may not require a PHY circuit.

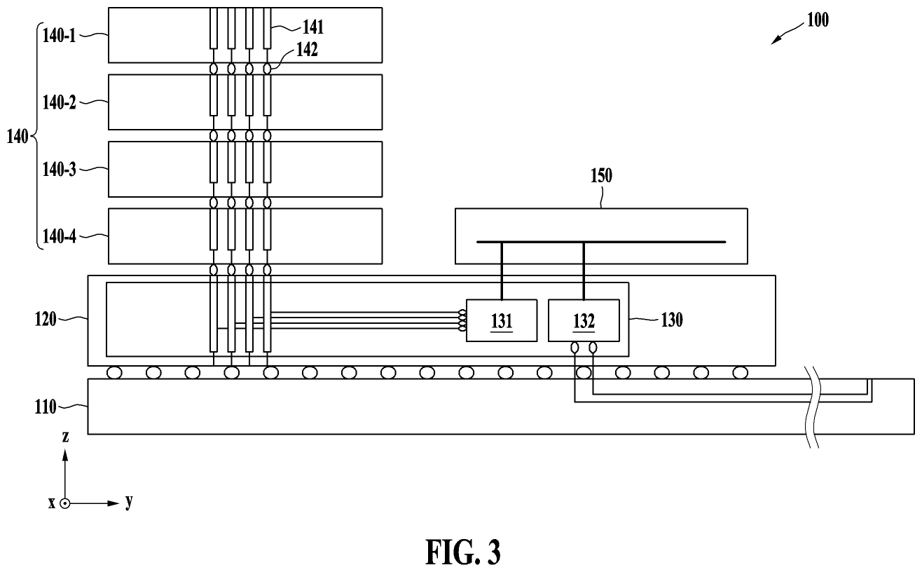

FIG. 3 is a diagram illustrating an example of the semiconductor package according to an embodiment.

Referring to FIG. 3, each memory die (e.g., the memory die 140-1, the memory die 140-2, the memory die 140-3, and/or the buffer die 140-4) of the at least one second die 140, according to an embodiment, may be physically connected to the redistribution layer 120 and/or the interposer 130 through a through electrode 141. The through electrode 141 may transmit an electrical signal by vertically penetrating the inside of the memory die (e.g., the memory die 140-1, the memory die 140-2, the memory die 140-3, and/or the buffer die 140-4) and may efficiently transmit the data of the at least one second die 140 to the redistribution layer 120 and/or the interposer 130. Data lines of the memory dies (e.g., the memory die 140-1, the memory die 140-2, the memory die 140-3, and/or the buffer die 140-4) may be connected to the interposer 130 via the through electrode 141. The through electrode 141 may be, for example, a through-silicon via (TSV) that penetrates a silicon substrate. The TSV may provide a high-speed path for rapidly transmitting the data generated by the at least one second die 140 to the interposer 130 without data loss and may maintain signal integrity in the semiconductor package.

For example, an electrical connection between the at least one second die 140 and the redistribution layer 120 and/or the interposer 130 may vary depending on the direction in which a wiring layer of the interposer 130 is positioned. An active region of the interposer 130 may be formed beneath the surface of a wafer where active elements, such as a transistor, are positioned and may perform data operations and processing. A wiring layer region (e.g., a back end of the line (BEOL) region) formed above the active region may include multiple layers of metal wires and may serve to transmit a signal generated in the active region.

When the wiring layer of the interposer 130 is at an upper portion of the interposer 130, that is, if it is a face-to-face connection, the wiring layer region of the interposer 130 may be at the upper portion and may be directly connected to a wiring layer region of the at least one second die 140. In this case, the interposer 130 may form a through electrode for connection with the outside and may be connected to an external circuit (e.g., a circuit of the substrate 110).

When the wiring layer of the interposer 130 is at a lower portion of the interposer 130, that is, if it is a face-to-back connection, the wiring layer region of the interposer 130 may be at the lower portion and may not be directly connected to the at least one second die 140. In this case, the through electrode may penetrate the interposer 130 and may be connected to the at least one second die 140 above the interposer 130. A signal generated in the at least one second die 140 may be transmitted to the wiring layer region of the interposer 130 via the through electrode 141 and the wiring layer of the lower part of the interposer 130 may be directly connected to the external circuit without the through electrode 141.

The electrical connection between the at least one second die 140 and the interposer 130 may be established via a micro bump 142 in addition to the through electrode 141. The micro bump 142 may provide a contact between the at least one second die 140 and/or the interposer 130 and may ensure stable transmission of a data signal. The data signal transmitted via the micro bump 142 may be directly connected to the memory controller 131 in the interposer 130, simplifying a data transmission path and minimizing signal latency. However, the micro bump 142 may be an example of a data pin, and other types of data pins may be used. For example, other types of bumps, such as a copper (Cu) bump or a solder bump, may be used as a pin for data transmission. Alternatively, a hybrid bonding scheme in which a die is directly connected to a die may be used.

For example, a data line of the at least one second die 140 may be directly connected to the redistribution layer 120 and/or the interposer 130 in the semiconductor package 100, removing the need for a PHY circuit. Since data may be rapidly and efficiently processed by directly connecting the data line to the memory controller 131, data transmission speed may be improved, and the overall performance of the system may be optimized. This design may be particularly advantageous in high-performance computing and memory-intensive application fields.

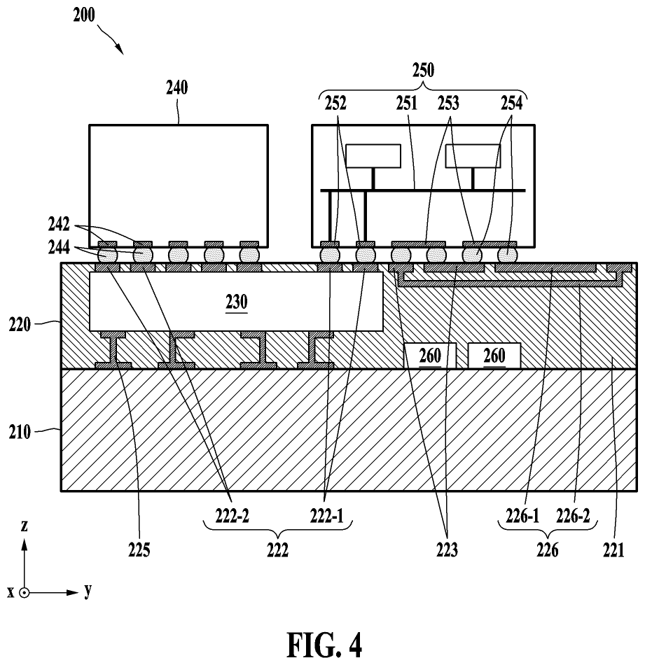

FIG. 4 is a cross-sectional view schematically illustrating a cross-section of a semiconductor structure 200, according to an embodiment. Hereinafter, it may be understood that the semiconductor structure 200 may be example of an intermediate structure created while forming a semiconductor package, a partial region of a complete semiconductor package, or the complete semiconductor package itself.

Referring to FIG. 4, the semiconductor structure 200 may include a substrate 210, a redistribution layer 220, an interposer 230, a first die 250, a second die 240, and an electronic element 260. The semiconductor package may be formed by performing molding and dicing on the semiconductor structure 200 as described below.

A silicon interposer may be used to connect a plurality of dies including a memory die and/or a processor die. An increase in silicon interposer size reduces the number of silicon interposers that may be produced in one wafer. The yield loss due to defects caused in a large-area silicon interposer may increase the price of the semiconductor package. According to an embodiment, the above-described problems may be reduced by installing a plurality of dies (e.g., the second die 240 and the first die 250) of the semiconductor structure 200 by using the redistribution layer (RDL) 220 and the interposer 230 of a small size that is embedded in the RDL 220.

Meanwhile, one of the major problems in a multi-chip package is the difficulty in verifying the mounting quality of each die. Each die may be mounted by using a connection terminal, such as a solder ball or a solder bump. In addition, it is possible that bonding may not be properly done due to a defective shape of this connection terminal, damage caused in a bonding process, or a foreign substance caught between bonding parts. According to an embodiment, as described below, a bonding state of each die may be tested in a simple manner.

The first die 250 may be, for example, a processor die (e.g., a logic die), but examples are not limited thereto. The first die 250 may be installed on the RDL 220. The first die 250 may include an internal circuit 251, a first connection pad 252, a plurality of dummy patterns 253, and a first connection terminal 254.

The internal circuit 251 may transmit an electrical signal internally by connecting a plurality of circuits (e.g., cores) provided inside the first die 250. For example, the internal circuit 251 may include a system bus (e.g., the system bus 151 of FIG. 2).

The first connection pad 252 may be electrically connected to the internal circuit 251 and may transmit an electrical signal or power between the internal circuit 251 and the outside (e.g., the RDL 220). The first connection pad 252 may be directly bonded to at least one of redistribution pads 222 (e.g., a first redistribution pad 222-1) formed on the RDL 220 or may be indirectly bonded thereto through the first connection terminal 254 to be electrically connected to the interposer 230 through the at least one of the redistribution pads 222.

A dummy pattern 253 may be electrically insulated from the internal circuit 251. The dummy pattern 253 may be a part where electricity does not flow while using the complete semiconductor package. The plurality of dummy patterns 253 may be electrically insulated from one another within the first die 250. The dummy pattern 253 may be formed in a region where the first connection pad 252 is not formed. The dummy pattern 253 may be directly bonded to a bonding pattern 223 formed on the RDL 220 or may be indirectly bonded thereto through the first connection terminal 254 such that the first die 250 may be stably fixed to the RDL 220. In other words, the dummy pattern 253 may improve the mechanical strength of the semiconductor structure 200. In addition, according to an embodiment, a physical bonding state between the first die 250 and the RDL 220 may be tested by using the dummy pattern 253 as described below.

A plurality of the first connection terminals 254 may be formed on the first connection pad 252 and/or the dummy pattern 253 and may form a physical and electrical connection with the bonding pattern 223 and/or a first redistribution pad 222-1 of the RDL 220. For example, the first connection terminal 254 may be provided in the form of a solder bump or a solder ball.

The second die 240 may be a memory die (e.g., HBM). The second die 240 may be installed on the RDL 220. For example, the second die 240 may be installed to completely overlap with the interposer 230 in a stacking direction (e.g., a +/−Z direction). This shape allows a conductor (e.g., a second connection pad 242, a second connection terminal 244, and a second redistribution pad 222-2) configured to transmit a signal or power that is transmitted from the second die 240 to the interposer 230 or from the interposer 230 to the second die 240 to be installed in the stacking direction, helping the high-speed transmission of the signal or power. For example, many conductors may be formed in the stacking direction across a large area where the second die 240 overlaps with the interposer 230. This structure may be advantageous in transmitting, at high speed, a signal of HBM in a structure where a plurality of memory dies is stacked. For example, a conductor extending in parallel to a plane (e.g., an X-Y plane) perpendicular to the stacking direction may not be provided between the second die 240 and the interposer 230. For example, the area of the second die 240 and the number of second dies 240 may vary depending on the area of the interposer 230.

The second connection pad 242 may be electrically connected to a circuit provided inside the second die 240 and may transmit an electrical signal or power between the internal circuit and the outside (e.g., the RDL 220). The second connection pad 242 may be directly bonded to the redistribution pad 222 formed on the RDL 220 or may be indirectly bonded thereto through the second connection terminal 244 to be electrically connected to the interposer 230 through the redistribution pad 222. The first connection pad 252 and the second connection pad 242 may be electrically connected to a circuit of the first die 250, the interposer 230, and/or a circuit of the second die 240. Thus, a user may indirectly verify whether the first connection pad 252 and the second connection pad 242 are properly bonded to a target through whether the semiconductor structure 200 normally operates.

The second connection terminal 244 may be formed on the second connection pad 242 and may form a physical and electrical connection with at least one of the redistribution pads 222 (e.g., the second redistribution pad 222-2). For example, the second connection terminal 244 may be provided in the form of a solder bump or a solder ball.

The RDL 220 may be installed on the substrate 210. The first die 250 and the second die 240 may be installed on one side of the RDL 220 and the interposer 230 may be embedded in the RDL 220. For example, the RDL 220 may be manufactured based on (e.g., including) polymer or dielectric in a large area with a relatively low cost. For example, wiring inside the RDL 220 may be used for low-speed communication or power transmission, and communication between the first die 250 and the second die 240 may be implemented through the interposer 230 (e.g., an interposer 230 die including an active circuit) embedded in the RDL 220. This configuration allows the manufacturing of the semiconductor structure 200 with excellent performance and economic efficiency.

For example, the RDL 220 may rearrange a pad at a desired position by additionally forming a metal layer to the pad that has been already formed on the substrate 210. To rearrange a pad position, the RDL 220 may be formed in a structure where a plurality of layers is stacked through multiple deposition processes. The RDL 220 may include an insulator 221, the redistribution pads 222, the bonding pattern 223, a redistribution pattern 225, and at least one testing line 226.

The insulator 221 may be formed of an insulating material. The insulator 221 may insulate a plurality of redistribution pads 222 from one another and may reduce the problem of electrical interference among the plurality of redistribution pads 222. For example, the insulator 221 may include insulating polymer or photosensitive insulating material (e.g., photo-imageable dielectric (PID)).

The redistribution pattern 225 may be formed of a conductive material and may at least partially penetrate the insulator 221 to be electrically connected to other adjacent components (e.g., the substrate 210, the interposer 230, the first die 250 and/or the second die 240). For example, the redistribution pattern 225 may be installed between the interposer 230 and the substrate 210, installed between the interposer 230 and the first die 250, or installed between the interposer 230 and the second die 240. The redistribution pattern 225 may include at least one of the redistribution pads 222 connected to an electronic element (e.g., an interposer 230, a second die 240, a first die 250, and an electronic element 260) that is inside or outside the insulator 221, a redistribution line extending in the horizontal direction (e.g., a X-Y plane direction) of the insulator 221, and a redistribution via that is connected to the redistribution line and/or the redistribution pad 222 by at least partially penetrating the insulator 221.

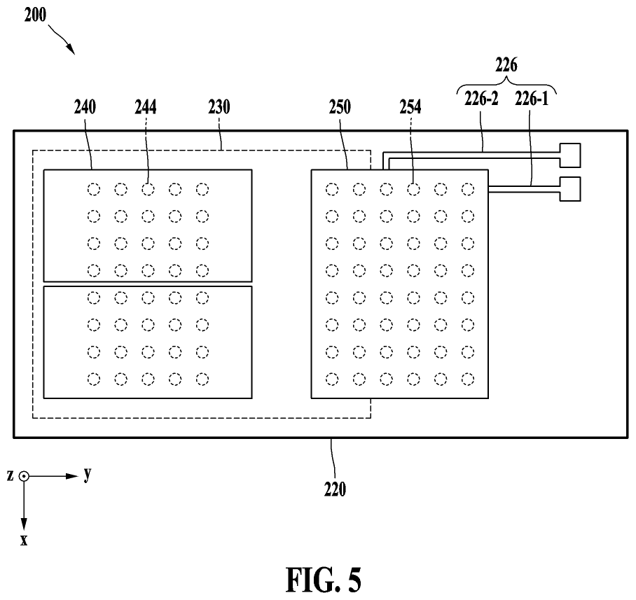

For example, the redistribution pads 222 may include (i) the first redistribution pad 222-1 that is at (e.g., in or on) the surface of the insulator 221 and is configured to electrically connect between the interposer 230 and the first die 250 (e.g., the first connection pad 252), and (ii) the second redistribution pad 222-2 that is at (e.g., in or on) the surface of the insulator 221 and is configured to electrically connect between the interposer 230 and the second die 240 (e.g., the second connection pad 242). Although FIG. 5 illustrates an example of directly installing the redistribution pad 222 on the interposer 230, it should be noted that it is just an example and the redistribution pattern 225 may be additionally installed between the redistribution pad 222 and the interposer 230.

The bonding pattern 223 may be at (e.g., in or on) the surface of the RDL 220. The bonding pattern 223 may be a part where electricity does not flow while using the complete semiconductor package and may be understood as a part used for improving mechanical bonding stability between the first die 250 and the RDL 220. As an area occupied by the interposer 230 in the RDL 220 is reduced, the plurality of bonding patterns 223 may be included to stably bond a region outside the interposer 230 of the first die 250 to the RDL 220. The plurality of bonding patterns 223 may be electrically insulated from one another by the insulator 221 in the RDL 220.

The bonding pattern 223 may be electrically connected to at least one of the plurality of dummy patterns 253. The plurality of bonding patterns 223 and the plurality of dummy patterns 253 may be arranged to form a daisy chain when the first die 250 is installed on the RDL 220. In other words, when the first die 250 is installed on the RDL 220, any one of the plurality of dummy patterns 253 may be alternately connected in series to any one of the plurality of bonding patterns 223 such that some or all of the plurality of patterns (e.g., the dummy patterns 253 and the bonding patterns 223) may be connected in series. This structure may allow the monitoring of the mounting quality of the first die 250 in a non-destructive manner by using the at least one testing line 226 without cross-sectional analysis on the semiconductor package.

The at least one testing line 226 may include a first testing line 226-1 connected to any one of the plurality of bonding patterns 223, and a second testing line 226-2 connected to another one of the plurality of bonding patterns 223. Meanwhile, although FIG. 4 illustrates an example of positioning the first testing line 226-1 and the second testing line 226-2 at different heights, it should be noted that it is just an example. As described below, the first testing line 226-1 and the second testing line 226-2 may be positioned at the same height.

The first testing line 226-1 and the second testing line 226-2 may be respectively connected to both ends of the daisy chain. In other words, while the first die 250 is installed in the RDL 220, at least one dummy pattern 253 of the plurality of dummy patterns 253 and at least one bonding pattern 223 of the plurality of bonding patterns 223 may form a daisy chain having the first testing line 226-1 and the second testing line 226-2 as both ends. A test pad that is exposed to the outer surface of the RDL 220 may be provided at an end of each of the first testing line 226-1 and the second testing line 226-2. An operator may test a physical bonding state of the bonding pattern 223 and the dummy pattern 253 through a process (e.g., resistance measurement) of verifying an electrical connection state between a pair of test pads. In addition, a bonding state of all the patterns (e.g., the dummy pattern 253 and the bonding pattern 223) provided in one daisy chain may be verified through one test, and this may reduce test time.

As described above, a bonding state of the first connection pad 252, the first redistribution pad 222-1, the second connection pad 242, and the second redistribution pad 222-2 may be indirectly verified through whether the semiconductor package normally operates, but a bonding state of the bonding pattern 223 that is electrically insulated from a circuit for the operation of the semiconductor package may not be verified in said manner. For example, to verify the bonding state, destructive analysis performed on each bonding structure by sampling a portion of the semiconductor package may be used. Meanwhile, according to an embodiment, testing may be performed in a non-destructive manner without such cross-sectional analysis, and this may increase production throughput. In addition, as test time may be shorter than before, more semiconductor packages may be tested during the same time. This may improve the reliability of a production line.

In a daisy chain structure, the dummy pattern 253 together with the bonding pattern 223 may form a thermal path that may transmit heat generated in the first die 250 to the outside. As a result, such a daisy chain structure may serve as a means of improving the heat dissipation performance of the whole semiconductor package.

The interposer 230 may be embedded in the RDL 220 and may transmit an electrical signal between the first die 250 and the second die 240. The interposer 230 may be electrically connected to the first redistribution pad 222-1 and may not be electrically connected to the plurality of bonding patterns 223. For example, the interposer 230 may be a semiconductor chip or an interposer die including an active circuit (e.g., a memory controller) that may amplify or control a signal transmitted between the first die 250 and the second die 240.

In the height direction (e.g., the +/−Z direction) of the semiconductor structure 200, the interposer 230 may not overlap with the plurality of bonding patterns 223. This structure may allow the first die 250 and the second die 240 to be connected to each other by using the interposer 230 having a small area. Thus, this may reduce the problems of a large-area silicon interposer such as, for example, the problems of warpage, reliability, and price. In addition, the electronic element 260 (e.g., a manual element) that is additionally provided in a free space, in which the interposer 230 is not positioned, of the RDL 220 may be installed. For example, in the height direction of the semiconductor structure 200, the interposer 230 may overlap with all second connection pads 242 which are electrically connected to the internal circuit 251 of the second die 240, and may partially overlap with the first die 250.

For example, if the first die 250 is a processor die, and the second die 240 is a memory die, in the height direction of the semiconductor package, all the regions of the second die 240 (e.g., a memory die) may overlap with the interposer 230. For example, in the height direction of the semiconductor package, an edge region toward the second die 240 of the first die 250 (e.g., a processor die) may overlap with the interposer 230 and the remaining region of the first die 250 may not overlap with the interposer 230.

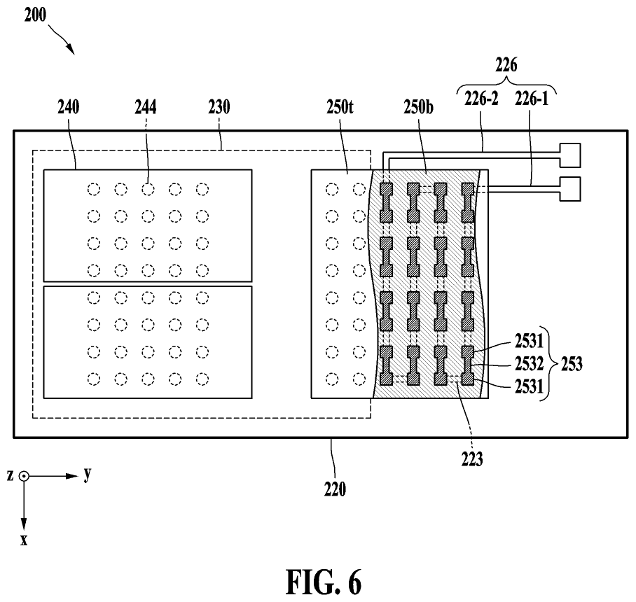

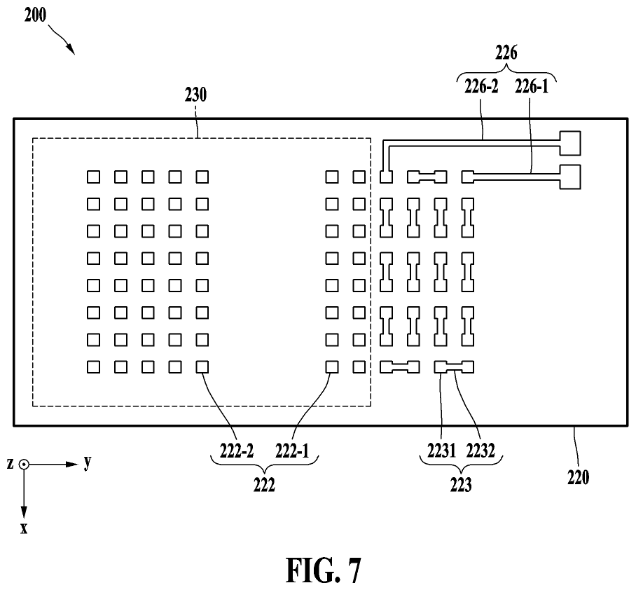

FIG. 5 is a top view of the semiconductor structure according to an embodiment. FIG. 6 is a top view of the semiconductor structure of FIG. 5, including a partial cutaway view of a portion of a first die. FIG. 7 is a top view of the semiconductor structure of FIG. 5, but where a first die and a second die are removed.

Referring to FIGS. 5 to 7, the semiconductor structure 200, according to an embodiment, may include the substrate 210 (refer to FIG. 4), the RDL 220, the interposer 230, the first die 250, and the second die 240.

For example, each of the first die 250 and the second die 240 may be installed on the RDL 220 through each of the first connection terminal 254 and the second connection terminal 244.

FIG. 6 illustrates a top surface 250t and a bottom surface 250b of the first die 250 by cutting a part of the first die 250 to show the internal structure of the bottom surface 250b of the first die 250. As illustrated in the drawings, the dummy patterns 253 may be installed at (e.g., in or on), for example, the bottom surface 250b of the first die 250. The plurality of dummy patterns 253 may be insulated from one another in the first die 250, but, if the first die 250 is installed on the RDL 220, the plurality of dummy patterns 253 may be electrically interconnected through the bonding pattern 223 on the RDL 220. For example, the dummy pattern 253 may be formed at the same height as a height of the first connection pad 252 (refer to FIG. 4) of the first die 250. This structure may allow the dummy pattern 253 to be formed together with the first connection pad 252 in the same process with no need to add a separate process to form the dummy pattern 253. The dummy pattern 253 may include a dummy pad 2531 and a dummy line 2532.

The dummy pad 2531 may be formed at a position corresponding to the bonding pad 2231 formed on the RDL 220. In other words, along the height direction (e.g., the +/−Z direction) of the semiconductor structure 200, a plurality of dummy pads 2531 may respectively overlap with a plurality of bonding pads 2231. For example, the dummy pads 2531 may be connected to the first connection terminals 254.

The dummy line 2532 may interconnect a pair of dummy pads 2531 of the plurality of dummy pads 2531. For example, along the height direction of the semiconductor structure 200, the dummy line 2532 may be formed to not overlap with the bonding line 2232 formed on the RDL 220.

The RDL 220 may include the redistribution pad 222, the bonding pattern 223, and the testing line 226. The redistribution pad 222 may include the first redistribution pad 222-1 overlapping with the first connection pad 252 (refer to FIG. 4) and the second redistribution pad 222-2 overlapping with the second connection pad 242 (refer to FIG. 4) in the height direction of the semiconductor structure 200.

The bonding pattern 223 may include the bonding pad 2231 that overlaps with the dummy pad 2531 in the height direction of the semiconductor structure 200 and the bonding line 2232 that interconnects a pair of bonding pads 2231 of the plurality of bonding pads 2231.

The testing lines 226 may include the first testing line 226-1 and the second testing line 226-2 respectively connected to a pair of bonding pads 2231 at both ends of the daisy chain of the plurality of bonding pads 2231. For example, the first testing line 226-1 and the second testing line 226-2 may be formed at the same height as a height of the bonding pattern 223 in the height direction (e.g., the +/−Z direction) of the semiconductor structure 200 as illustrated in the drawings. For example, the bonding pattern 223, the first testing line 226-1, and the second testing line 226-2 may be on substantially the same plane (e.g., the X-Y plane). For example, the first redistribution pad 222-1, the second redistribution pad 222-2, the plurality of bonding patterns 223, the first testing line 226-1, and the second testing line 226-2 may be on substantially the same plane. As such, conductors on substantially the same plane may be formed in the same process. Thus, there is no need to add a metal layer or a mask only for the testing lines 226, and this may reduce process time and cost. According to an embodiment, there is no need to interpose an additional layer for testing, and a structure (e.g., the testing line 226 or the bonding line 2232) for testing may be formed on substantially the same plane as that of a metal layer (e.g., the redistribution pad 222) for the operation of the semiconductor package. This may reduce the increase of the height of the whole semiconductor structure 200.

For example, the plurality of dummy patterns 253 formed on the first die 250, the plurality of bonding patterns 223 formed on the redistribution layer 220, and the testing lines 226 may form one daisy chain. For example, as illustrated in FIG. 6, all the dummy patterns 253 of the first die 250 may be included in one daisy chain. This configuration may allow whether any part of the first die 250 is poorly bonded to be verified with only one test, and this may reduce test time.

Meanwhile, although all the bonding pads 2231 formed on the RDL 220 are illustrated as being included in the daisy chain, it should be noted that some of the bonding pads 2231 may not be included in the daisy chain. For example, the bonding pad 2231 in a region where a bonding failure is unlikely to occur may be designed to be not included in the daisy chain. For example, if heat is applied to the first die 250 in an attachment process of the first connection terminal 254 or the like, the first die 250 may be deformed. In this case, the bonding in the outermost region may be the most vulnerable. In this regard, it should be noted that, for example, the daisy chain may be designed to include the bonding pad 2231 in the region where bonding is vulnerable without including the remaining bonding pads 2231. This configuration may allow material costs to be reduced while maintaining the accuracy of tests at a certain level or higher. For example, the daisy chain may include at least two of the plurality of bonding patterns 223 at the outermost region from the center of the semiconductor structure 200. For example, the daisy chain may not include the bonding pattern 223 that is the closest to the center of the semiconductor structure 200 of the plurality of bonding patterns 223.

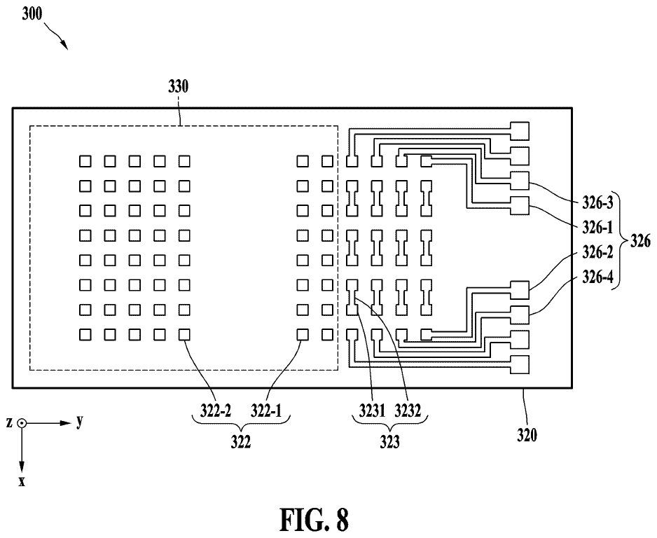

FIG. 8 is a top view of an RDL according to an embodiment.

Referring to FIG. 8, a semiconductor structure 300, according to an embodiment, may include the substrate 210 (refer to FIG. 4), an RDL 320, an interposer 330, the first die 250 (refer to FIG. 6), and the second die 240 (refer to FIG. 6). For example, the first die 250 and the second die 240 may have the same structure as the structure illustrated in FIGS. 4 to 6, and the repeated description thereof may be omitted.

For example, as illustrated in the drawings, a plurality of daisy chains may be formed on the RDL 320. FIG. 8 illustrates an example of four daisy chains formed lengthily in an X-axis direction and spaced apart from one another in a Y-axis direction. This configuration allows a poorly bonded part to be localized by examining each daisy chain. The RDL 320 may include (i) at least one redistribution pad 322 including a first redistribution pad 322-1 and a second redistribution pad 322-2, (ii) a bonding pattern 323 including a bonding pad 3231 and a bonding line 3232, and (iii) a plurality of testing lines 326.

Each of the plurality of testing lines 326 may be connected to respective ends of each of the plurality of daisy chains formed by the dummy pattern 253 (refer to FIG. 6) of the first die 250 and the bonding pattern 323. For example, a first testing line 326-1 and a second testing line 326-2 may be connected to respective ends of a first daisy chain, and a third testing line 326-3 and a fourth testing line 326-4 may be connected to respective ends of a second daisy chain electrically insulated from the first daisy chain. A user may examine a bonding state of the bonding pattern 323 on the first daisy chain by using the first testing line 326-1 and the second testing line 326-2, and may examine a bonding state of the bonding pattern 323 on the second daisy chain by using the third testing line 326-3 and the fourth testing line 326-4.

In other words, the plurality of dummy patterns 253 (refer to FIG. 6) may include a first dummy pattern included in the first daisy chain and a second dummy pattern included in the second daisy chain electrically insulated from the first daisy chain. The plurality of bonding patterns 323 may include a first bonding pattern included in the first daisy chain connected in series to the first dummy pattern and a second bonding pattern included in the second daisy chain connected in series to the second dummy pattern. In this case, the first testing line 326-1 and the second testing line 326-2 may be respectively connected to respective ends of the first daisy chain, and the third testing line 326-3 and the fourth testing line 326-4 may be respectively connected to respective ends of the second daisy chain.

For example, the plurality of daisy chains may be formed to extend in a first horizontal direction (e.g., a +/−X direction) and may be spaced apart from one another in a second horizontal direction (e.g., a +/−Y direction). This configuration allows a bonding state to be examined by each row or each column. Meanwhile, it should be noted that this shape is just an example and the plurality of daisy chains may be formed in various shapes.

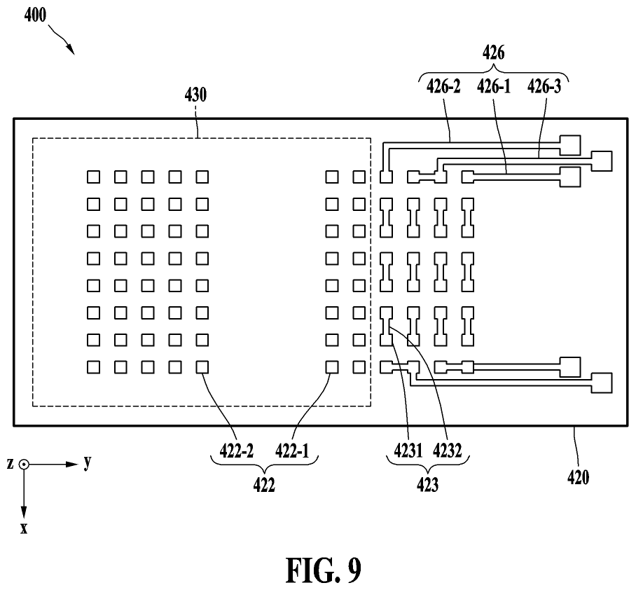

FIG. 9 is a top view of an RDL according to an embodiment.

Referring to FIG. 9, a semiconductor structure 400, according to an embodiment, may include the substrate 210 (refer to FIG. 4), an RDL 420, an interposer 430, the first die 250 (refer to FIG. 6), and the second die 240 (refer to FIG. 6). For example, the first die 250 and the second die 240 may have the same structure as the structure illustrated in FIGS. 4 to 6, and repeated description thereof may be omitted.

The RDL 420 may include (i) at least one redistribution pad 422 including a first redistribution pad 422-1 and a second redistribution pad 422-2, (ii) a bonding pattern 423 including a bonding pad 4231 and a bonding line 4232, and (iii) a plurality of testing lines 426.

The plurality of testing lines 426 may include a first testing line 426-1 and a second testing line 426-2 respectively connected to ends of a daisy chain formed on the RDL 420, and at least one middle testing line 426-3 connected to a middle of the same daisy chain.

Like the case of a plurality of daisy chains being provided, a poorly bonded part may be localized by using the middle testing line 426-3. For example, by examining an electrical connection state between the first testing line 426-1 and the middle testing line 426-3 or examining an electrical connection state between the second testing line 426-2 and the middle testing line 426-3, a bonding state of each of bonding pads 4231 positioned in different regions may be tested. For example, an electrical connection state between the first testing line 426-1 and the second testing line 426-2 may be examined first to select a normal product, and, for a defective product, a poorly bonded part may be localized by using the middle testing line 426-3 as described above.

FIG. 9 illustrates the total of three middle testing lines 426-3 being formed in addition to the first testing line 426-1 and the second testing line 426-2. Using the total of five testing lines 426 as such may enable a bonding state to be examined by each row or each column as illustrated in FIG. 8. Meanwhile, the structure FIG. 8 may require a total of eight testing lines 326 to examine a bonding state by each row or each column. Accordingly, using the middle testing line 426-3 may reduce material costs.

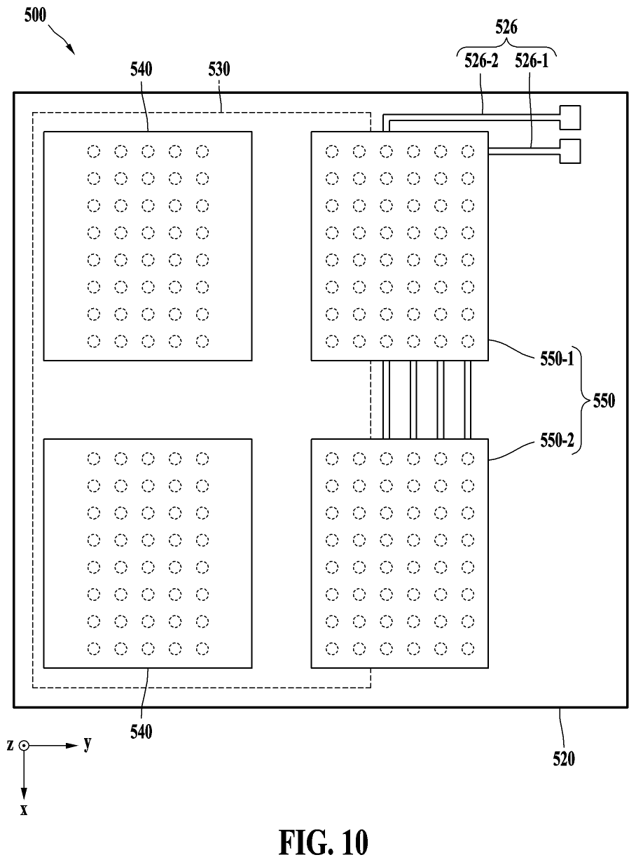

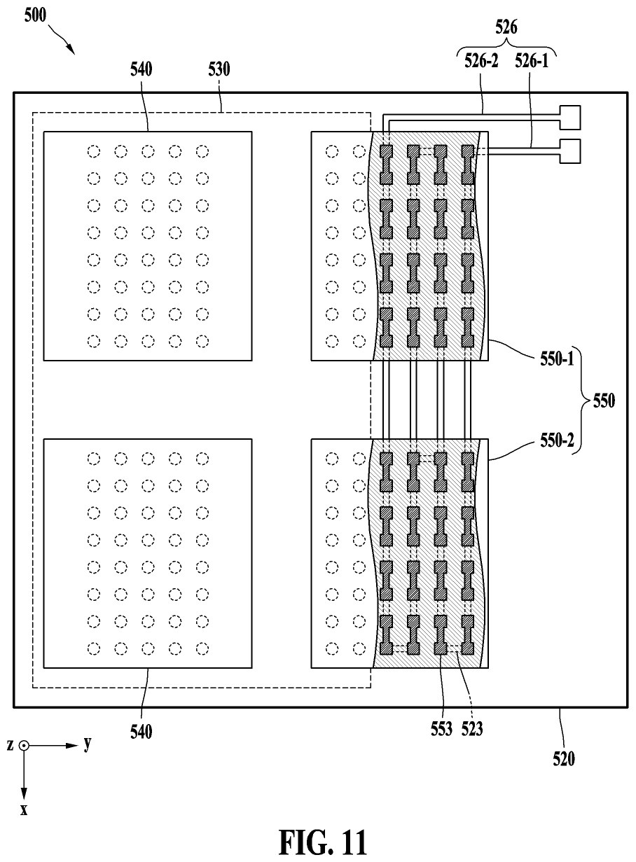

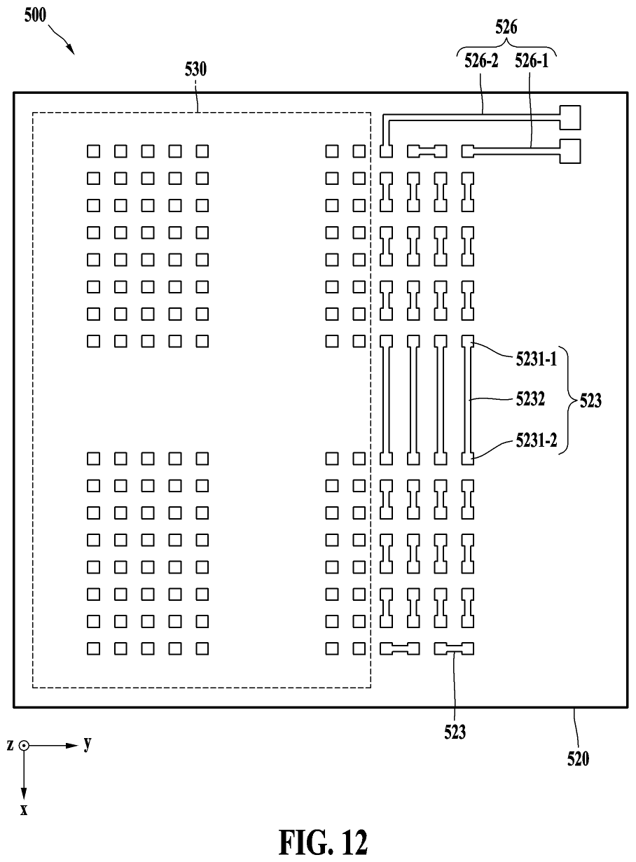

FIG. 10 is a top view of a semiconductor structure according to an embodiment. FIG. 11 is a top view of the semiconductor structure of FIG. 10, including a partial cutaway view of a portion of a first die. FIG. 12 is a top view of the semiconductor structure of FIG. 10, but where a first die and a second die are removed

Referring to FIGS. 10 to 12, a semiconductor structure 500, according to an embodiment, may include the substrate 210 (refer to FIG. 4), an RDL 520, an interposer 530, at least one first die 550, and a second die 540.

The at least one first die 550 may include, for example, a 1-1st die 550-1 and a 1-2nd die 550-2 on the RDL 520. According to an embodiment, if a plurality of dies (e.g., the 1-1st die 550-1 and the 1-2nd die 550-2) is bonded to the same RDL 520, a bonding state of the plurality of dies (e.g., the 1-1st die 550-1 and the 1-2nd die 550-2) may be examined by using one daisy chain.

The RDL 520 may include bonding patterns 523 and at least one testing line 526. For example, at least one bonding pattern 523 of the bonding patterns 523 may include a 1-1st bonding pad 5231-1, a 1-2nd bonding pad 5231-2, and a bonding line 5232. The at least one testing line 526 may include a first testing line 526-1 and a second testing line 526-2.

The 1-1st bonding pad 5231-1 may overlap with a dummy pattern 553 formed on the 1-1st die 550-1, in the height direction (e.g., a +/−Z direction) of the semiconductor structure 500. The 1-2nd bonding pad 5231-2 may overlap with the dummy pattern 553 formed on the 1-2nd die 550-2, in the height direction (e.g., the +/−Z direction) of the semiconductor structure 500. The bonding line 5232 may interconnect the 1-1st bonding pad 5231-1 and the 1-2nd bonding pad 5231-2. This structure may allow the plurality of dummy patterns 553 of each of the 1-1st die 550-1 and the 1-2nd die 550-2 and the plurality of bonding patterns 523 on the RDL 520 to form one daisy chain. Accordingly, whether any part of the 1-1st die 550-1 is poorly bonded may be verified with only one test, and thus, test time may be reduced. Although FIG. 11 illustrates two dies being connected by one daisy chain, it should be noted that this is just an example and three or more dies may be connected by one daisy chain.

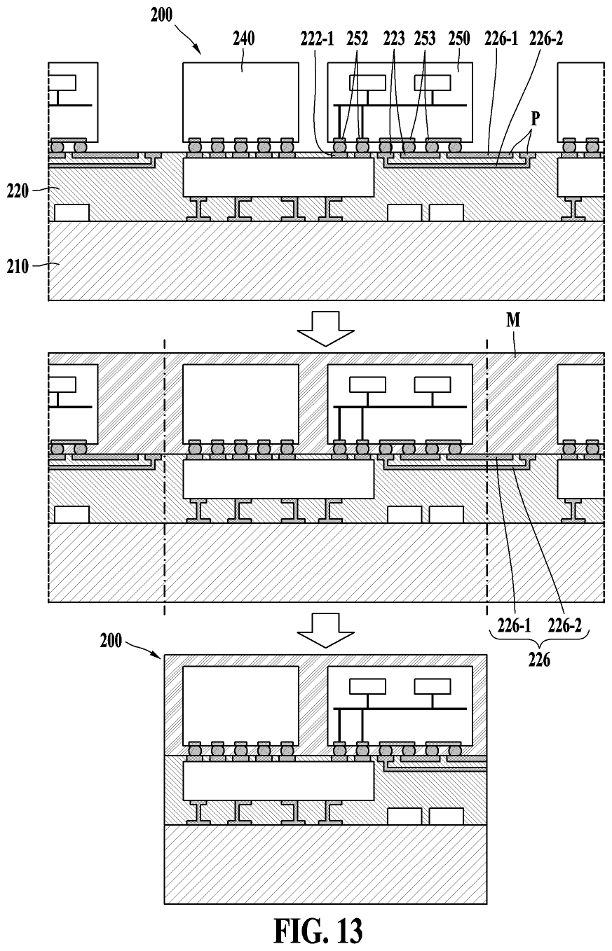

FIG. 13 is a drawing illustrating a method of manufacturing the semiconductor package according to an embodiment.

Referring to FIG. 13, the semiconductor package 200, according to an embodiment, may be formed at, for example, a wafer level. For example, a test pad P provided in each of the first testing line 226-1 and the second testing line 226-2 may be placed outside a saw line for forming a final semiconductor package 200. Other electronic components may not be formed in a region overlapping with the test pad P in the height direction of the semiconductor package 200. In this structure, after testing the mounting quality of the semiconductor package 200 by using the test pad P, the size of the whole semiconductor package 200 may be reduced by removing the region.

A method for manufacturing the semiconductor package 200, according to an embodiment, may include (i) an operation of installing the first die 250 on the RDL 220 by connecting the first redistribution pad 222-1 to the first connection pad 252 and connecting the plurality of bonding patterns 223 to the plurality of dummy patterns 253, (ii) an operation of testing a bonding state between the first die 250 and the RDL 220 by measuring resistance of a daisy chain by using the first testing line 226-1 and the second testing line 226-2, (iii) an operation of surrounding the first die 250 with a molding material M such that the first die 250 is not exposed to the outside, and (iv) an operation of dicing in a direction (e.g., a vertical direction) crossing the first testing line 226-1 and the second testing line 226-2. Unless otherwise stated, it should be noted that the order of the operations is not limited and at least one operation may be omitted.

For example, as illustrated in FIG. 13, after the test is completed, an upper region of the RDL 220 including the first die 250, the second die 240, and the test pad P may be covered with the molding material M, and the semiconductor package 200 may be formed by dicing along the saw line. This method may allow a molding process to be performed by using a general mold with no need to use a special mold.

Meanwhile, through this manufacturing method, a cut part of the first testing line 226-1 and the second testing line 226-2 may be exposed to the outside of the semiconductor package 200. However, the cut part may be a part where current does not flow while using the complete semiconductor package 200. Thus, even without separate insulation, the operational reliability of the semiconductor package 200 may not be undermined.

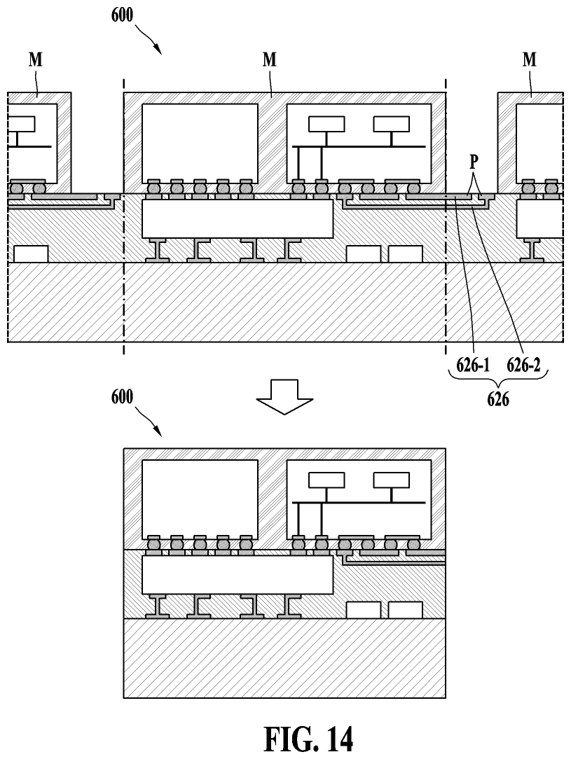

FIG. 14 is a drawing illustrating a method of manufacturing a semiconductor package according to an embodiment.

Referring to FIG. 14, in a molding process for manufacturing a semiconductor package 600, according to one embodiment, by adjusting the shape of a mold for molding, the test pad P provided in a testing line may be positioned outside a molding layer formed by the molding material M. For example, the molding process may be performed with an end (e.g., the test pad P) of each of a first testing line 626-1 and a second testing line 626-2 outside a molding region. Unlike the example illustrated in FIG. 13, this method may allow a test on a daisy chain to be performed not only before the molding process but also after the molding process.

As described above, although non-limiting example embodiments have been described with reference to the drawings, a person skilled in the art may apply various technical modifications and variations based thereon, which are included in the scope of the present disclosure. For example, suitable results may be achieved if the described techniques are performed in a different order and/or if components in a described system, architecture, device, or circuit are combined in a different manner and/or replaced or supplemented by other components or their equivalents.

Therefore, other implementations, other embodiments, and equivalents are also within the scope of the present disclosure.

What is claimed is:

1. A semiconductor structure comprising:
a first die comprising:
an internal circuit;
a first connection pad configured to transmit an electrical signal or power between the internal circuit and an outside of the first die; and
a plurality of dummy patterns electrically insulated from the internal circuit; and
a redistribution layer comprising:
a first redistribution pad electrically connected to the first connection pad;
a plurality of bonding patterns electrically connected to at least one of the plurality of dummy patterns;
a first testing line connected to one of the plurality of bonding patterns, and
a second testing line connected to another one of the plurality of bonding patterns,
wherein the first die is on the redistribution layer,
wherein at least one dummy pattern, from among the plurality of dummy patterns, and at least two bonding patterns, from among the plurality of bonding patterns, form a daisy chain, and
wherein the first testing line and the second testing line are respective ends of the daisy chain.

2. The semiconductor structure of claim 1, wherein the plurality of bonding patterns, the first testing line, and the second testing line are on substantially a same plane.

3. The semiconductor structure of claim 1, wherein the at least two bonding patterns of the daisy chain are at an outermost region of the semiconductor structure in a horizontal direction of the semiconductor structure.

4. The semiconductor structure of claim 1, wherein a bonding pattern that is closest to a center of the semiconductor structure in a horizontal direction of the semiconductor structure, from among the plurality of bonding patterns, is not included in the daisy chain.

5. The semiconductor structure of claim 1, wherein the semiconductor structure further comprises an interposer that is in the redistribution layer, the interposer being electrically connected to the first redistribution pad, and not electrically connected to the plurality of bonding patterns.

6. The semiconductor structure of claim 5, wherein the interposer comprises a semiconductor chip comprising an active circuit configured to amplify or control a signal that is transmitted to the first die.

7. The semiconductor structure of claim 5, wherein the interposer does not overlap with the plurality of bonding patterns in a height direction of the semiconductor structure.

8. The semiconductor structure of claim 5, wherein the semiconductor structure further comprises a second die overlapping with the interposer in a height direction of the semiconductor structure, and
wherein the interposer is configured to transmit an electrical signal between the first die and the second die.

9. The semiconductor structure of claim 8, wherein the first die comprises a processor die, and the second die comprises a memory die.

10. The semiconductor structure of claim 8, wherein the second die comprises an internal circuit and second connection pads that are electrically connected to the internal circuit of the second die,
wherein the interposer overlaps with the second connection pads in the height direction, and
wherein the interposer partially overlaps with the first die in the height direction.

11. The semiconductor structure of claim 8, wherein the interposer comprises a second redistribution pad electrically connected to a second connection pad of the second die, and
wherein the first redistribution pad, the second redistribution pad, the plurality of bonding patterns, the first testing line, and the second testing line are on substantially a same plane.

12. The semiconductor structure of claim 1, wherein the plurality of dummy patterns are electrically insulated from one another in the first die.

13. The semiconductor structure of claim 1, wherein at least one of the plurality of dummy patterns is alternately connected in series to at least one of of the plurality of bonding patterns to form the daisy chain.

14. The semiconductor structure of claim 1, wherein the daisy chain is a first daisy chain,
wherein the plurality of dummy patterns comprises:
a first dummy pattern in the first daisy chain; and
a second dummy pattern in a second daisy chain, the second daisy chain electrically insulated from the first daisy chain,
wherein the plurality of bonding patterns comprises:
a first bonding pattern in the first daisy chain, the first bonding pattern connected in series to the first dummy pattern; and
a second bonding pattern in the second daisy chain, the second bonding pattern connected in series to the second dummy pattern, and
wherein the redistribution layer further comprises a third testing line and a fourth testing line that are respectively connected to respective ends of the second daisy chain.

15. The semiconductor structure of claim 1, wherein the redistribution layer further comprises at least one middle testing line connected to a middle of the daisy chain.

16. The semiconductor structure of claim 1, wherein the first die comprises a 1-1st die on the redistribution layer, and a 1-2nd die on the redistribution layer,
wherein at least one bonding pattern from among the plurality of bonding patterns comprises:
a 1-1st bonding pad overlapping with, in a height direction of the semiconductor structure, a first dummy pattern, from among the plurality of dummy patterns, of the 1-1st die ;
a 1-2nd bonding pad overlapping with, in the height direction, a second dummy pattern, from among the plurality of dummy patterns, of the 1-2nd die; and
a bonding line that connects the 1-1st bonding pad to the 1-2nd bonding pad.

17. The semiconductor structure of claim 1, wherein the semiconductor structure further comprises:
a molding layer surrounding the first die such that the first die is not exposed to an outside of the semiconductor structure; and
test pads at an end of each of the first testing line and the second testing line, respectively, the test pads being outside the molding layer.

18. A semiconductor package comprising:
a memory die;
a processor die comprising:
an internal circuit;
a first connection pad configured to transmit an electrical signal or power between the internal circuit and an outside of the processor die; and
a plurality of dummy patterns electrically insulated from the internal circuit;
a redistribution layer comprising:
a first redistribution pad electrically connected to the first connection pad;
a plurality of bonding patterns electrically connected to at least one of the plurality of dummy patterns;
a first testing line connected to a first bonding pattern from among the plurality of bonding patterns; and
a second testing line connected to a second bonding pattern from among the plurality of bonding patterns; and
an interposer die that is configured to transmit an electrical signal between the memory die and the processor die, the interposer die being in the redistribution layer.

19. The semiconductor package of claim 18, wherein
an entirety of the memory die overlaps with the interposer die in a height direction of the semiconductor package, and
an edge region of the processor die, towards the memory die, overlaps with the interposer die in the height direction, and a remaining region of the processor die does not overlap with the interposer die in the height direction.

20. A manufacturing method of a semiconductor package, the method comprising:
forming a redistribution pad and a plurality of bonding patterns on a redistribution layer;
forming a first testing line connected to a first bonding pattern from among the plurality of bonding patterns;
forming a second testing line connected to a second bonding pattern from among the plurality of bonding patterns;
placing the redistribution layer on a substrate;
connecting a logic die to the redistribution layer, wherein the redistribution layer includes a connection pad and a plurality of dummy patterns,, wherein the redistribution pad is connected to the connection pad, and at least one of the plurality of dummy patterns is connected to the plurality of bonding patterns such as to form a daisy chain, wherein the first testing line and the second testing line are respective ends of the daisy chain;
surrounding the logic die with a molding material such that the logic die is not exposed to an outside of the semiconductor package; and
dicing a structure, formed by the surrounding the logic die with the molding material, in a direction crossing the first testing line and the second testing line.
